(19) United States
(12) Patent Application Publication
(10) Pub. No.: US 2019/0113563 A1
(43) Pub. Date: Apr. 18, 2019

(54) SEMICONDUCTOR DEVICE

(71) Applicant: DENSO CORPORATION, Kariya-city (JP)

(72) Inventors: Sadahiro AKAMA, Kariya-city (JP); Hidekazu ONO, Hamamatsu-city (JP)

(21) Appl. No.: 16/228,889

(22) Filed: Dec. 21, 2018

Related U.S. Application Data
(63) Continuation of application No. PCT/JP2017/025872, filed on Jul. 18, 2017.

(30) Foreign Application Priority Data
Aug. 25, 2016 (JP) 2016-164999

(51) Int. Cl. G01R 31/26; G01R 19/00

(52) U.S. Cl. CPC G01R 31/2621; G01R 19/0092

(57) ABSTRACT

A semiconductor device includes a main switching element, a sense switching element, a sense resistor and an operational amplifier. The main switching element has a first terminal and a second terminal between which a load current flows. The sense switching element is connected to the main switching element to form a current mirror, and has a third terminal and a fourth terminal between which a sense current correlated with the load current flows. The sense resistor is arranged in a feedback path of the operational amplifier. A direction of the sense current flowing through the sense resistor is switchable according to a magnitude relationship between a potential of the first terminal and a potential of the second terminal or a magnitude relationship between the potential of the first terminal and the potential of the fourth terminal.

### CROSS REFERENCE TO RELATED APPLICATIONS

The present application is a continuation application of International Patent Application No. PCT/JP2017/025872 filed on Jul. 18, 2017, which designated the U.S. and claims the benefit of priority from Japanese Patent Application No. 2016464999 filed on Aug. 25, 2016. The entire disclosures of all of the above applications are incorporated herein by reference.

### TECHNICAL FIELD

The present disclosure relates to a semiconductor device for detecting a current.

### BACKGROUND

A shunt resistor or a current sensor may be used for detecting a current flowing through a power switching element such as an IGBT or a MOSFET. However, the shunt resistor may cause a power loss due to a current flowing through the shunt resistor itself, and the current sensor may be more expensive than the shunt resistor.

### SUMMARY

The present disclosure provides a semiconductor device including a main switching element, a sense switching element, a sense resistor and an operational amplifier. The main switching element has a first terminal and a second terminal between which a load current flows. The sense switching element is connected to the main switching element to form a current mirror, and has a third terminal and a fourth terminal between which a sense current correlated with the load current flows. The sense resistor is arranged in a feedback path of the operational amplifier. A direction of the sense current flowing through the sense resistor is switchable according to a magnitude relationship between a potential of the first terminal and a potential of the second terminal or a magnitude relationship between the potential of the first terminal and the potential of the fourth terminal.

### BRIEF DESCRIPTION OF THE DRAWINGS

The above and other objects, features and advantages of the present disclosure will become more apparent from the following detailed description made with reference to the accompanying drawings in which:

FIG. 1 is a circuit diagram showing a schematic configuration of a semiconductor device according to a first embodiment;

FIG. 2 is a circuit diagram showing a schematic configuration of a semiconductor device according to Modification 1;

FIG. 3 is a circuit diagram showing a schematic configuration of a semiconductor device according to Modification 2;

FIG. 4 is a circuit diagram showing a schematic configuration of a semiconductor device according to a second embodiment;

FIG. 5 is a circuit diagram showing a schematic configuration of a semiconductor device according to a third embodiment;

FIG. 6 is a circuit diagram showing a schematic configuration of a semiconductor device according to Modification 3;

FIG. 7 is a circuit diagram showing a schematic configuration of a semiconductor device according to a fourth embodiment; and

FIG. 8 is a circuit diagram showing a schematic configuration of a semiconductor device according to Modification 4.

### DETAILED DESCRIPTION

For example, a source voltage of MOSFET may be input to an operational amplifier and an output of the operational amplifier may be fed back to detect a current of a switching element accurately without using a shunt resistor and a current sensor.

In this case, however, although a current value of the current flowing from a drain to a source (for example, during power running) can be detected, a current value of the current flowing from the source to the drain (for example, during regeneration) cannot be detected.

For detecting the current during regeneration, a shunt resistor may be used. However, the use of the shunt resistor is not preferable from the viewpoint of a power loss.

Embodiments of the present disclosure will be described below with reference to the drawings. The same reference numerals are assigned to the same or equivalent parts in the following drawings.

### First Embodiment

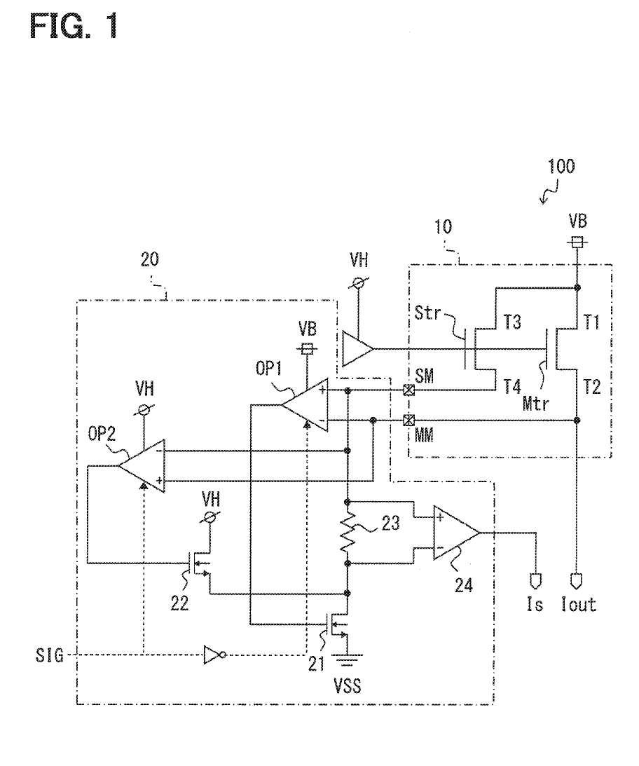

First, a schematic configuration of a semiconductor device in accordance with the present embodiment will be described with reference to FIG. 1.

As shown in FIG. 1, a semiconductor device 100 is a switch device that includes a power switching element 10 and a current detection unit 20 which detects an output current flowing through the power switching element. In the present embodiment, potentials to be supplied from a predetermined voltage source to terminals include a power supply potential VB, a boosted potential VH that is boosted to a potential higher than the power supply potential VB, and a reference potential VSS of a circuit. A magnitude relationship of those potentials is VH>VB>VSS. VSS is, for example, a ground potential, VB is, for example, a battery potential in a vehicle, and VH is a potential obtained by boosting the battery potential by a charge pump or the like.

The power switching element 10 includes a main MOS transistor Mtr, which is a main switching element for supplying an output current Iout to a load (not shown), and a sense MOS transistor Str whose drain is connected to a drain of the main MOS transistor in a current mirror connection.

The main MOS transistor Mtr is, for example, an Nch MOS transistor. A power supply is connected to a drain terminal T1, which is the first terminal, and has the power supply potential VB. On the other hand, a source terminal T2, which is a second terminal, is a terminal for extracting an output current Iout, which is a current flowing through the main MOS transistor Mtr. In other words, the load is connected to the source terminal T2. When a gate voltage is applied to a gate terminal when the potential of the source terminal T2 is lower than that of the drain terminal T1, that is, at the time of power running, the output current Iout flows from the drain terminal T1 toward the source terminal T2.

Conversely, even when the source terminal T2 is at a higher potential than that of the drain terminal T1, that is, at the time of regeneration, a synchronous rectification is performed in which the gate voltage is applied to turn on the main MOS transistor Mtr. As a result, the output current Iout flows from the source terminal T2 toward the drain terminal T1 based on a mirror ratio of the main MOS transistor Mtr and the sense MOS transistor Str.

As shown in FIG. 1, a potential of the source terminal T2 as the second terminal is denoted by MM, and the potential is applied to an inverting input terminal of a first operational amplifier OP1 and a non-inverting input terminal of a second operational amplifier OP2, which will be described later.

The sense MOS transistor Str is, for example, an Nch MOS transistor. The sense MOS transistor Str is connected to the main MOS transistor Mtr by a current mirror. In other words, a drain terminal T3, which is a third terminal, is connected to the drain terminal T1 of the main MOS transistor Mtr and is set to the power supply potential VB.

Then, the same gate voltage as that of the main MOS transistor Mtr is applied to the gate terminal. A sense current Is flows between the drain terminal T3 and a source terminal T4 as a fourth terminal of the sense MOS transistor Str. The sense current Is has a magnitude corresponding to the mirror ratio defined between the sense MOS transistor Str and the main MOS transistor Mtr, and a direction of the sense current Is is the same as the direction of the output current Iout. That is, when the gate voltage is applied to the gate terminal when the potential of the source terminal T4 is lower than that of the drain terminal T3, that is, at the time of power running, the sense current Is flows from the drain terminal T3 toward the source terminal T4.

Conversely, even when the source terminal T4 is at a higher potential than that of the drain terminal T3, that is, at the time of power regeneration, synchronous rectification is performed in which the gate voltage is applied to turn on the sense MOS transistor Str. As a result, the sense current Is flows from the source terminal T4 toward the drain terminal T3.

As shown in FIG. 1, the potential of the source terminal T4 as the fourth terminal is denoted by SM, and the potential is applied to the non-inverting input terminal of the first operational amplifier OP1 and the inverting input terminal of the second operational amplifier OP2, which will be described later.

As described above, the sense current Is correlates with the output current Tout. Therefore, if the sense current Is can be detected without directly measuring the output current Iout, the output current Tout can be known. In the following description of the sense current Is and the output current Tout, the direction of the current at the time of power running in which the current flows from the drain to the source is set to be positive, and the direction of the current at the time of regeneration set to be negative.

The current detection unit 20 uses a feedback current by the negative feedback operation of the operational amplifiers OP1 and OP2, which will be described in detail below, as the sense current Is. As shown in FIG. 1, the current detection unit 20 includes the first operational amplifier OP1, the second operational amplifier OP2, a first transistor 21, a second transistor 22, a sense resistor 23, and a sense current detection amplifier 24.

The first operational amplifier OP1 is a general operational amplifier that is driven using the power supply potential VB as a power supply. The source terminal T4 of the sense MOS transistor Str is connected to the non-inverting input terminal of the first operational amplifier OP1. The source terminal T2 of the main MOS transistor Mtr is connected to the inverting input terminal of the first operational amplifier OP1.

An output terminal of the first operational amplifier OP1 is connected to the gate terminal of the first transistor 21 formed of an NMOS. The source terminal of the first transistor 21 is connected to the reference potential VSS, and the drain terminal of the first transistor 21 is connected to the non-inverting input terminal of the first operational amplifier OP1 through the sense resistor 23. In other words, the output terminal of the first operational amplifier OP1 is connected to the non-inverting input terminal through the first transistor 21 and the sense resistor 23 in the stated order. The reference potential VSS is, for example, the ground potential GND.

As described above, the output terminal of the first operational amplifier OP1 is connected to the non-inverting input terminal through the sense resistor 23 by negative feedback. Then, when a potential difference occurs between the non-inverting input terminal and the inverting input terminal, a feedback current flows from the non-inverting input terminal toward the reference potential VSS, so that the potential difference between the non-inverting input terminal and the inverting input terminal is reduced.

In other words, this means that a current flows from the source terminal T4 of the sense MOS transistor Str toward the reference potential VSS, and the feedback current at that time flows to the sense resistor 23 as the sense current Is. Such a flow of the sense current Is occurs at the time of power running in which a potential SM of the source terminal T4 becomes lower than the power supply potential VB.

The second operational amplifier OP2 is a general operational amplifier that is driven using the boosted potential VH as a power supply. The source terminal T4 of the sense MOS transistor Str is connected to the inverting input terminal of the second operational amplifier OP2. The source terminal T2 of the main MOS transistor Mtr is connected to the non-inverting input terminal of the second operational amplifier OP2.

The output terminal of the second operational amplifier OP2 is connected to the gate terminal of the second transistor 22 formed of an NMOS. The drain terminal of the second transistor 22 is connected to the boosted potential VH, and the source terminal of the second transistor 22 is connected to the inverting input terminal of the second operational amplifier OP2 through the sense resistor 23. That is, the output terminal of the second operational amplifier OP2 is connected to the inverting input terminal through the second transistor 22 and the sense resistor 23 in the stated order.

As described above, the output terminal of the second operational amplifier OP2 is connected to the inverting input terminal through the sense resistor 23 by negative feedback. Then, when a potential difference occurs between the non-inverting input terminal and the inverting input terminal, a feedback current flows from the boosted potential VH toward the inverting input terminal, whereby the second operational amplifier OP2 operates so that the potential difference between the non-inverting input terminal and the inverting input terminal becomes small.

That is, this means that a current flows from the boosted potential VH toward the source terminal T4 of the sense MOS transistor Str, and the feedback current at this time flows to the sense resistor 23 as the sense current Is. Such a flow of the sense current Is occurs at the time of regeneration when the potential SM of the source terminal T4 becomes higher than the power supply potential VB, and is opposite to the direction of the sense current at the time of power running. In the present embodiment, since the boosted potential VH is higher than the power supply potential VB, the sense current flows even at the time of regeneration of SM>VB.

As shown in FIG. 1, a signal SIG for turning on or off each operation is input to the first operational amplifier OP1 and the second operational amplifier OP2. In this example, turning on the operational amplifier means outputting a signal from the output terminal by exerting a function as an amplifier. Further, turning off the operational amplifier means cutting off the signal output from the output terminal.

The signal SIG turns on the first operational amplifier OP1 and turns off the second operational amplifier OP2 when a magnitude relationship between the potential of the drain terminal T1 as the first terminal and the potential of the source terminal T2 as the second terminal is MM<VB, or when a magnitude relationship between the potential of the drain terminal T1 as the first terminal and the potential of the source terminal T4 as the fourth terminal is SM<VB. On the other hand, the signal SIG turns off the first operational amplifier OP1 and turns on the second operational amplifier OP2 when MM>VB or SM>VB.

The sense current detection amplifier 24 is a generally known operational amplifier. A non-inverting input terminal of the sense current detection amplifier 24 is connected to one end of the sense resistor 23 on the non-inverting input terminal side of the first operational amplifier OP1 or on the inverting input terminal side of the second operational amplifier OP2.

On the other hand, the other end of the sense resistor 23 is connected to the inverting input terminal of the sense current detection amplifier 24. Therefore, the sense current detection amplifier 24 outputs a positive output value correlated with the sense current value at the time power running in which the potential of the non-inverting input terminal is higher than that of the inverting input terminal.

On the other hand, the sense current detection amplifier 24 outputs a negative output value correlated with the sense current value at the time of regeneration in which the potential of the non-inverting input terminal is lower than that of the inverting input terminal.

Next, the operation and effect of adopting the semiconductor device 100 in accordance with the present embodiment will be described.

In the semiconductor device 100, the first operational amplifier OP1 is turned on and becomes effective, and the second operational amplifier OP2 is turned off and becomes ineffective at the time of power running in which SM<VB or MM<VB. The first operational amplifier OP1 performs a negative feedback operation so that SM becomes equal to MM. In this process, the first transistor 21 is turned on and a feedback current flows from the non-inverting input terminal of the first operational amplifier OP1 toward the reference potential VSS through the sense resistor 23, and the feedback current is detected as the sense current.

As described above, the semiconductor device 100 can detect the sense current at the time of power running in a state where a drain-source voltage of the main MOS transistor Mtr and a drain-source voltage of the sense MOS transistor Str are maintained at the same value. Therefore, the output current Tout at the time of power running can be detected with high accuracy while maintaining the correct mirror ratio without causing a potential difference deviation between the main MOS transistor Mtr and the sense MOS transistor Str due to the Early effect.

In the semiconductor device 100, the second operational amplifier OP2 is turned on to be effective, and the first operational amplifier OP1 is turned off to be ineffective at the time of regeneration in which SM>VB or MM>VB. The second operational amplifier OP2 performs a negative feedback operation so that SM becomes equal to MM. In this process, the second transistor 22 is turned on, a feedback current flows from the boosted potential VH through the sense resistor 23 toward the non-inverting input terminal of the second operational amplifier OP1, and the feedback current is detected as the sense current.

As described above, the semiconductor device 100 can detect the sense current at the time of regeneration in a state in which the drain-source voltage of the main MOS transistor Mtr and the drain-source voltage of the sense MOS transistor Str are maintained at the same value. Therefore, at the time of synchronous rectification, the output current Tout at the time of regeneration can be detected with high accuracy while maintaining the correct mirror ratio without causing a potential difference deviation between the main MOS transistor Mtr and the sense MOS transistor Str due to the Early effect.

As described above, the semiconductor device 100 can detect the sense current Is correlated with the output current Tout with high accuracy, including the direction of the sense current Is. In addition, in the semiconductor device 100, since a shunt resistor for current detection is not provided at the source terminal T2 which is the output terminal of the main MOS transistor Mtr, there is no power loss with respect to the output current.

Accordingly, a semiconductor device capable of detecting a bidirectional current at the time of power running and regeneration with high accuracy while reducing a power loss can be provided.

### Modification 1

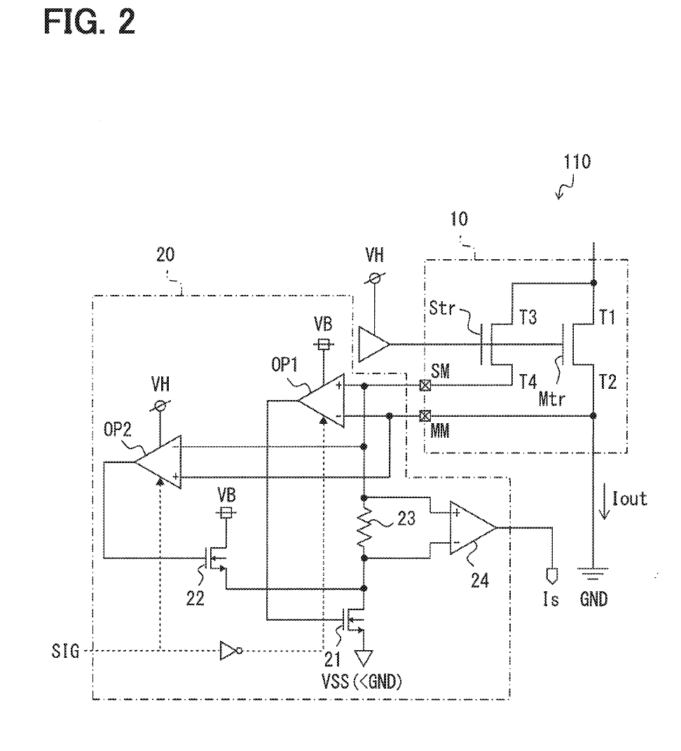

In the first embodiment described above, a configuration in which the drain terminal T1 of the main MOS transistor Mtr is set to the power supply potential VB, and a so-called high-side MOS transistor is assumed with respect to the load has been described, but as shown in FIG. 2, the same configuration can be adopted for a low-side MOS transistor with respect to the load.

One of differences of the semiconductor device 110 from the semiconductor device 100 in the first embodiment resides in that the source terminal T2 of the main MOS transistor Mtr is connected to the ground potential GND and the load is connected to the drain terminal T1. Another difference resides in that the potential VSS of the source terminal of the first transistor 21 is set to a potential lower than the ground potential GND, and the drain terminal of the second transistor 22 is connected to the power supply potential VB.

The first difference arises from the fact that the main MOS transistor Mtr is connected to the low-side with respect to the load.

In the second differences, it is essential to set the potential VSS of the source terminal of the first transistor 21 to a potential lower than the ground potential GND. At the time of power running, the first operational amplifier OP1 causes a feedback current to flow toward the reference potential VSS so that the potential SM of a specific inverting input terminal becomes equal to the potential MM (=GND) of the inverting input terminal. This operation can be realized by setting the reference potential VSS to a potential lower than the ground potential GND.

A potential connected to the drain terminal of the second transistor 22 is the power supply potential VB in the present modification, but may be the boosted potential VH.

In the present modification, similarly to the first embodiment, the first operational amplifier OP1 is turned on at the time of power running and the second operational amplifier OP2 is turned on at the time of regeneration, thereby being capable of detecting the sense current Is correlated with the output current Tout with high accuracy including the direction of the sense current Is.

### Modification 2

In the first embodiment described above, an example has been described in which the first transistor 21 and the second transistor 22 that configure the feedback path when the first operational amplifier OP1 and the second operational amplifier OP2 are rendered effective are N-channel MOS transistors.

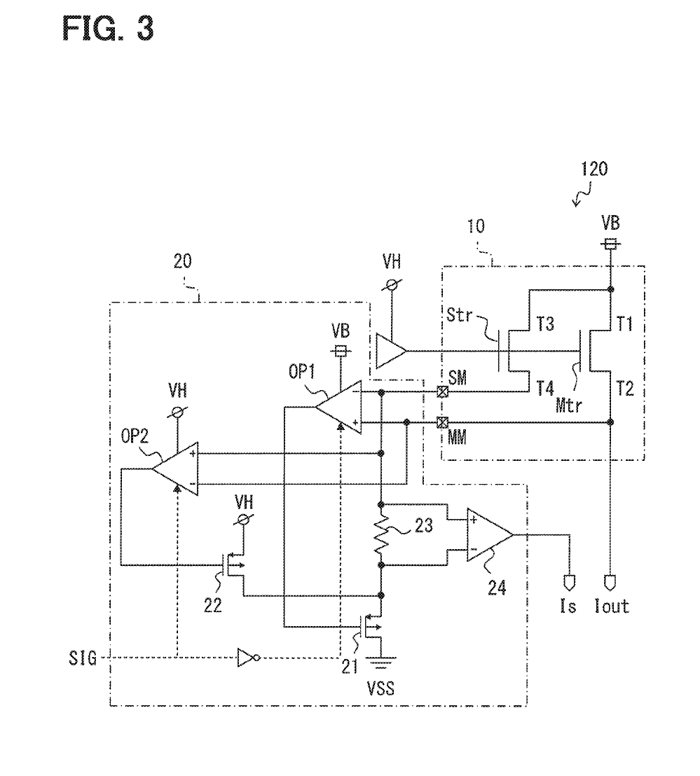

In this example, the first transistor 21 and the second transistor 22 may operate so as to provide a feedback path when the first operational amplifier OP1 and the second operational amplifier OP2 are rendered effective, respectively, and are not limited to the Nch MOS transistors. For example, the first transistor 21 and the second transistor 22 in the semiconductor device 120 shown in FIG. 3 are P-channel MOS transistors (PMOS).

In the semiconductor device 120, the configuration of the input terminal of the first operational amplifier OP1 is also reversed from that of the first embodiment. The configuration of the input terminal of the second operational amplifier OP2 is also reversed from that of the first embodiment. In a specific example, the source terminal T2 of the main MOS transistor Mtr is connected to the non-inverting input terminal of the first operational amplifier OP1 and the inverting input terminal of the second operational amplifier OP2. The source terminal T4 of the sense MOS transistor Str is connected to the inverting input terminal of the first operational amplifier OP1 and the non-inverting input terminal of the second operational amplifier OP2.

With the configuration described above, at the time of power running, the sense current Is flows from the inverting input terminal of the first operational amplifier OP1 toward the reference potential VSS in the feedback path to which the first operational amplifier OP1 belongs. At the time of regeneration, the sense current Is flows from the boosted potential VH to the non-inverting input terminal of the second operational amplifier OP2 in the feedback path to which the second operational amplifier OP2 belongs.

That is, similarly to the first embodiment, the sense current Is correlated with the output current Iout can be detected with high accuracy including the direction of the sense current Is.

### Second Embodiment

In the first embodiment and Modifications a and 2 of the first embodiment, a configuration having two operational amplifiers for generating the feedback current as the sense current has been described. On the other hand, a semiconductor device 130 according to the present embodiment exhibits the same effects as those of the first embodiment by the only operational amplifier OP3.

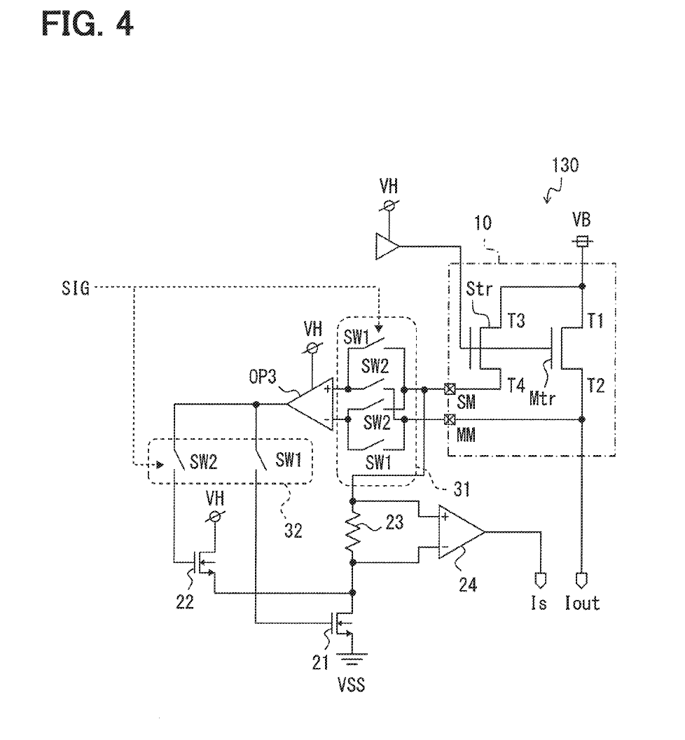

In the semiconductor device 130 according to the present embodiment, as shown in FIG. 4, only one operational amplifier OP3 is connected to the same power switching element 10 as that in the first embodiment. The boosted potential VH is input to the operational amplifier OP3 as the power supply, and the two input terminals are connected to the source terminals T2 and T4 of the main MOS transistor Mtr and the sense MOS transistor Str through the first switch circuit 31. The output terminal of the operational amplifier OP3 is connected to the first transistor 21 and the second transistor 22 through the second switch circuit 32.

Specifically, as shown in FIG. 4, the first switch circuit 31 includes two switches SW1 and two switches SW2. The source terminal T2, which is the second terminal of the main MOS transistor Mtr, is connected to the inverting input terminal of the operational amplifier OP3 through the switch SW1, and is connected to the non-inverting input terminal through the switch SW2.

That is, the source terminal T2 is connected to the inverting input terminal when the switch SW1 is on, and is connected to the non-inverting input terminal when the switch SW2 is on. The source terminal T4, which is the fourth terminal of the sense MOS transistor Str, is connected to the non-inverting input terminal of the operational amplifier OP3 through the switch SW1, and is connected to the inverting input terminal through the switch SW2.

That is, the source terminal T4 is connected to the non-inverting input terminal when the switch SW1 is on, and is connected to the inverting input terminal when the switch SW2 is on. The sense resistor 23 is connected to an intermediate point between the fourth terminal T4 and the first switch circuit 31.

The second switch circuit 32 has one switch SW1 and one switch SW2. The output terminal of the operational amplifier OP3 is input to the gate terminal of the first transistor 21 through the switch SW1. On the other hand, the output terminal is also connected to the gate terminal of the second transistor 22 through the switch SW2. The drain terminal of the first transistor 21 is connected to the non-inverting input terminal of the operational amplifier OP3 through the sense resistor 23, and the source terminal of the second transistor 22 is connected to the non-inverting input terminal of the operational amplifier OP3 through the sense resistor 23.

That is, the operational amplifier OP3 forms a negative feedback circuit that forms a feedback path including the first transistor 21 and the sense resistor 23 when the switch SW1 is turned on, and forms a negative feedback circuit that forms a feedback path including the second transistor 22 and the sense resistor 23 when the switch SW2 is turned on. In other words, when the switch SW1 is turned on, the operational amplifier OP3 performs the same function as that of the first operational amplifier OP1 in the first embodiment. On the other hand, when the switch SW2 is turned on, the operational amplifier OP3 performs the same function as the second operational amplifier OP2 in the first embodiment.

In the first embodiment, an example has been described in which the signals SIG for turning on and off the operational amplifiers OP1 and OP2 are input to the operational amplifiers OP1 and OP2 in accordance with the magnitude relationship between the potential of the drain terminal T1 as the first terminal and the potential of the source terminal T2 as the second terminal. On the other hand, the signal SIG in the present embodiment controls on/off of the switch SW1 and the switch SW2 in the first switch circuit 31 and the second switch circuit 32. The switch SW1 and the switch SW2 are synchronized with each other, and the switch SW2 is turned off when the switch SW1 is turned on. When the switch SW2 is on, the switch SW1 is turned off.

The signal SIG turns on the switch SW1 and turns off the switch SW2 when the magnitude relationship between the potential of the drain terminal T1 as the first terminal and the potential of the source terminal T2 as the second terminal is MM<VB, or when the magnitude relationship between the potential of the drain terminal T1 as the first terminal and the potential of the source terminal T4 as the fourth terminal is SM<VB (at the time of power running). On the other hand, when MM>VB (or SM>VB) (at the time of regeneration), the signal SIG turns off the switch SW1 and turns on the switch SW2.

As a result, it is possible to detect both of the sense current at the time of power running and the sense current at the time of regeneration by the single operational amplifier OP3. In addition, the number of operational amplifiers having a large circuit scale can be reduced as compared with the first embodiment and Modifications 1 and 2 of the first embodiment.

### Third Embodiment

Similar to the second embodiment, a semiconductor device 140 according to the present embodiment also has a circuit configuration capable of detecting output currents at the time of power running and at the time of regeneration using only one operational amplifier OP4.

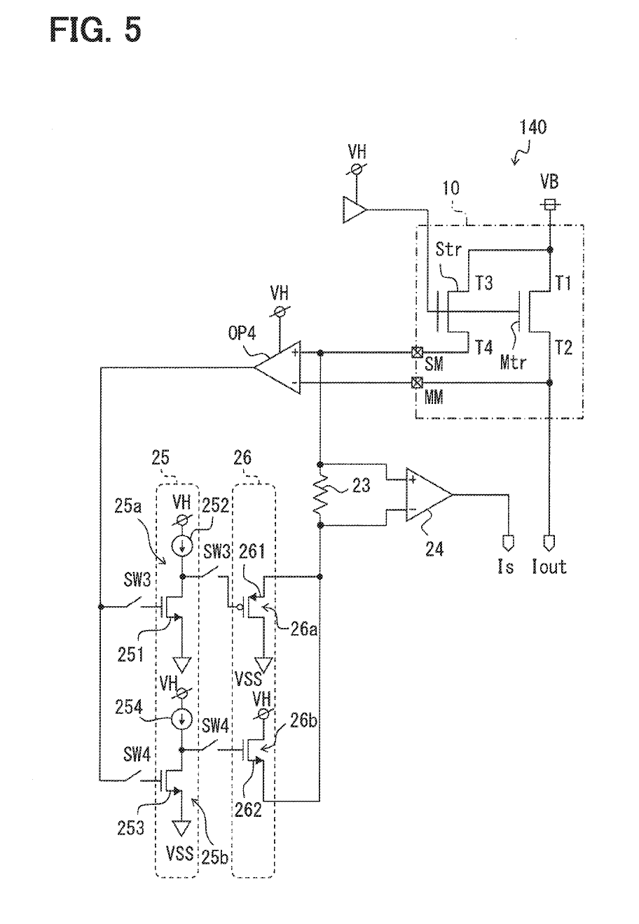

As shown in FIG. 5, in the present semiconductor device 140, only one operational amplifier OP4 is connected to the same power switching element 10 as that in the first embodiment. A boosted potential VH is input to the operational amplifier OP4 as a power supply. A source terminal T4 of a sense MOS transistor Str is connected to a non-inverting input terminal of the operational amplifier OP4, and a source terminal T2 of a main MOS transistor Mtr is connected to an inverting input terminal of the operational amplifier OP4.

An output terminal of the operational amplifier OP4 is connected to a voltage adjustment circuit 25 configured to output a voltage corresponding to the output of the operational amplifier OP4. The voltage regulated by the voltage adjustment circuit 25 is connected to a buffer 26 which regulates the direction of the feedback current relating to the supply or extraction of the current to or from the non-inverting input terminal of the operational amplifier OP4. The buffer 26 is connected to the non-inverting input terminal of the operational amplifier OP4 through the sense resistor 23.

That is, the operational amplifier OP4 configures a negative feedback circuit in which the output of the operational amplifier OP4 is fed back to the non-inverting input terminal through the voltage adjustment circuit 25, the buffer 26, and the sense resistor 23. The feedback current flowing through the feedback path forming the negative feedback is the sense current Is, and is detected by the sense current detection amplifier 24 in the same manner as that in the first and second embodiments.

The voltage adjustment circuit 25 includes a first adjustment circuit 25a and a second adjustment circuit 25b. The first adjustment circuit 25a and the second adjustment circuit 25b are independent of each other and have the same circuit configuration.

That is, the first adjustment circuit 25a includes an NMOS transistor 251 and a constant current source 252. The constant current source 252 and the NMOS transistor 251 are connected in series in the stated order between the boosted potential VH and the reference potential VSS. The output of the operational amplifier OP4 is input to the gate terminal of the NMOS transistor 251, and a potential of an intermediate point between the constant current source 252 and the NMOS transistor 251 is varied in accordance with the output of the operational amplifier OP4.

The switch SW3 is interposed between the first adjustment circuit 25a and the output terminal of the operational amplifier OP4, and when the switch SW3 is turned on, the voltage corresponding to the output of the operational amplifier OP4 is output from the intermediate point between the constant current source 252 and the NMOS transistor 251.

Substantially like the first adjustment circuit 25a, the second adjustment circuit 25b includes an NMOS transistor 253 and a constant current source 254. The constant current source 254 and the NMOS transistor 253 are connected in series in the stated order between the boosted potential VH and the reference potential VSS. The output of the operational amplifier OP4 is input to the gate terminal of the NMOS transistor 253, and a potential of an intermediate point between the constant current source 254 and the NMOS transistor 253 is varied in accordance with the output of the operational amplifier OP4.

The switch SW4 is interposed between the second adjustment circuit 25b and the output terminal of the operational amplifier OP4, and when the switch SW4 is turned on, the voltage corresponding to the output of the operational amplifier OP4 is output from the intermediate point between the constant current source 254 and the NMOS transistor 253.

As shown in FIG. 5, the buffer 26 includes a first buffer 26a and a second buffer 26b.

The first buffer 26a includes a PMOS transistor 261. An output of the first adjustment circuit 25a in the voltage adjustment circuit 25 is input to a gate terminal of the PMOS transistor 261. The reference potential VSS is connected to a source terminal of the PMOS transistor 261, and a drain terminal of the PMOS transistor 261 is connected to the non-inverting input terminal of the operational amplifier OP4 through the sense resistor 23.

The second buffer 26b includes an NMOS transistor 262. An output of the second adjustment circuit 25b in the voltage adjustment circuit 25 is input to a gate terminal of the NMOS transistors 262. The boosted potential VH is connected to a drain terminal of the NMOS transistor 262, and a source terminal of the NMOS transistor 262 is connected to the non-inverting input terminal of the operational amplifier OP4 through the sense resistor 23.

As described above, the buffer 26 is an output stage in which both of the first buffer 26a and the second buffer 26b have a source follower configuration, and a feedback current flows based on the output of the voltage adjustment circuit 25.

A switch SW3 and a switch SW4 are interposed between the operational amplifier OP4 and the voltage adjustment circuit 25 for turning on and off the connection between the operational amplifier OP4 and the voltage adjustment circuit 25. The switch SW3 and the switch SW4 are interposed between the voltage adjustment circuit 25 and the buffer 26 for turning on and off the connection between the switch SW3 and the switch SW4.

In a specific example, the first adjustment circuit 25a of the voltage adjustment circuit 25 is connected to the output terminal of the operational amplifier OP4 through the switch SW3, and is connected to the first buffer 26a through another switch SW3. On the other hand, the second adjustment circuit 25b of the voltage adjustment circuit 25 is connected to the output terminal of the operational amplifier OP4 through the switch SW4, and is connected to the second buffer 26b through another switch SW4.

At the time of powering, the switch SW3 is turned on and the switch SW4 is turned off. As a result, a feedback path between the output terminal and the non-inverting input terminal of the operational amplifier OP4 becomes a path through the first adjustment circuit 25a, the first buffer 26a, and the sense resistor 23. The first buffer 26a has the same function as that of the first transistor 21 in the first embodiment, so that the sense current flows from the non-inverting input terminal of the operational amplifier OP4 toward the reference potential VSS at the time of power running.

On the other hand, at the time of regeneration, the switch SW4 is turned on and the switch SW3 is turned off. As a result, the feedback path between the output terminal and the non-inverting input terminal of the operational amplifier OP4 becomes a path through the second adjustment circuit 25b, the second buffer 26b, and the sense resistor 23. The second buffer 26b has the same function as that of the second transistor 22 in the first embodiment, so that the sense current flows from the boosted potential VH toward the non-inverting input terminal of the operational amplifier OP4 at the time of regeneration.

The switch SW3 and the switch SW4 are turned on and off by the control signal SIG in the same manner as that in the second embodiment. When a magnitude relationship between the potential of the drain terminal T1 as the first terminal and the potential of the source terminal T2 as the second terminal is MM<VB, or when the magnitude relationship between the potential of the drain terminal T1 as the first terminal and the potential of the source terminal T4 as the fourth terminal is SM<VB (at the time of power running), the signal SIG turns on the switch SW3 and turns off the switch SW4. On the other hand, when MM>VB (or SM>VB) (at the time of regeneration), the signal SIG turns off the switch SW3 and turns on the switch SW4.

As described above, the semiconductor device 140 can detect the sense current at the time of regeneration in a state in which a drain-source voltage of the main MOS transistor Mtr and a drain-source voltage of the sense MOS transistor Str are maintained at the same value.

In the first embodiment and the second embodiment, the first transistor 21 related to power running is of the source grounded type, and the second transistor 22 related to regeneration is of the source follower type. Since the gains of the operational amplifiers OP1 to OP3 are different between the power running time and the regeneration time, there is a risk that the feedback of the output becomes difficult. On the other hand, in the semiconductor device 140 according to the present embodiment, since both of the first buffer 26a and the second buffer 26b have the source follower configuration, the feedback by the operational amplifier OP4 can be facilitated.

### Modification 3

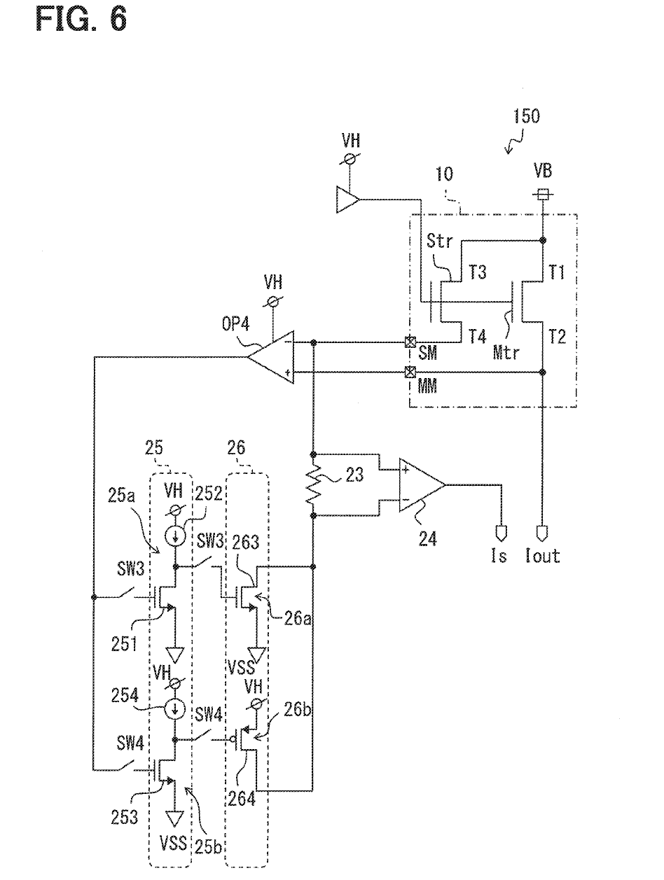

Although the buffer 26 in the third embodiment is an example in which both the first buffer 26a and the second buffer 26b are output stages having a source follower configuration, the buffer 26 may have a source grounded configuration. As shown in FIG. 6, the semiconductor device 150 differs from the semiconductor device 140 of the third embodiment in the buffer 26 and the operational amplifier OP4.

Specifically, the first buffer 26a in the buffer 26 is replaced with an NMOS transistor 263. An output of the first adjustment circuit 25a in the voltage adjustment circuit 25 are input to a gate terminal of the NMOS transistor 263. The reference potential VSS is connected to a source terminal of the NMOS transistor 263, and a drain terminal of the NMOS transistor 263 is connected to the inverting input terminal of the operational amplifier OP4 through the sense resistor 23.

Similarly, the second buffer 26b in the buffer 26 is replaced with a PMOS transistor 264. An output of the second adjustment circuit 25b in the voltage adjustment circuit 25 is input to a gate terminal of the PMOS transistors 264. The boosted potential V H is connected to a drain terminal of the PMOS transistor 264, and a source terminal of the PMOS transistor 264 is connected to the inverting input terminal of the operational amplifier OP4 through the sense resistor 23.

A connection of the non-inverting input terminal and the inverting input terminal of the operational amplifier OP4 is reversed with respect to the case of the third embodiment. In other words, the source terminal T2 of the main MOS transistor Mtr is connected to the non-inverting input terminal, and the source terminal T4 of the sense MOS transistor Str is connected to the inverting input terminal.

As described above, in the buffer 26 according to the present modification, both of the first buffer 26a and the second buffer 26b are configured to be grounded to the source. A feedback destination related to the negative feedback of the output of the operational amplifier OP4 is an inverting input terminal. Therefore, the feedback by the operational amplifier OP4 can be facilitated as compared with the first and second embodiments.

Also in the semiconductor device 150 configured as in the present modification, similarly to the third embodiment, a sense current corresponding to an output current at the time of power running or regeneration can be caused to flow. That is, the semiconductor device 150 can detect the sense current at the time of regeneration in a state in which a drain-source voltage of the main MOS transistor Mtr and a drain-source voltage of the sense MOS transistor Str are maintained at the same value.

### Fourth Embodiment

In each of the embodiments and Modifications described above, an example has been described in which the direction of the feedback current flowing through the sense resistor 23 is defined by controlling the operational amplifier or the switch to be rendered effective based on the signal SIG. In each embodiment and modification, the direction of the sense current is switched between the power running time and the regeneration time using the external signal SIG with a zero point of the sense current Is as a boundary.

On the other hand, a description will be given of an example in which the semiconductor device 160 according to the present embodiment automatically switches the direction of the feedback current, that is, the sense current Is, without using the signal SIG. The semiconductor device 160 automatically switches the direction of the sense current Is in the buffer 26 by preventing the sense current Is from becoming zero. Since the components except for the voltage adjustment circuit 25 and the buffer 26 are the same as those of the semiconductor device 140 described in the third embodiment, a detailed description of the same components will be omitted.

The voltage adjustment circuit 25 of the semiconductor device 160 includes an NMOS transistor 255 and a constant current source 256. The circuit configuration is the same as that of the first adjustment circuit 25a and the second adjustment circuit 25b in the third embodiment, and the constant current source 256 and the NMOS transistor 255 are connected in series in the stated order between the boosted potential VH and the reference potential VSS. The output of the operational amplifier OP4 is input to a gate terminal of the NMOS transistor 255, and a potential at an intermediate point between the constant current source 256 and the NMOS transistor 255 is varied in accordance with the output of the operational amplifier OP4.

The buffer 26 in the semiconductor device 160 is a so-called class AB buffer having a voltage follower configuration. The buffer 26 has a configuration in which a drain current flows through the transistor of the input stage even when the input voltage is zero. For that reason, an output voltage corresponding to the input voltage is obtained in a state in which the output of the buffer 26 is offset with respect to the input voltage. The circuit configuration will be described in detail below.

The buffer 26 includes an NMOS transistor 265, a PMOS transistor 267, a constant current source 266, and a constant current source 268 as an input stage. The constant current source 266 and the NMOS transistor 265, and the PMOS transistor 267 and the constant current source 268 are connected in series in the stated order between the boosted potential VH and the reference potential VSS.

The gate terminal of the NMOS transistor 265 is connected so as to have the same potential as that of the drain terminal. The gate terminal of the PMOS transistor 267 is connected so as to have the same potential as that of the source terminal. The output voltage of the voltage adjustment circuit 25 is input to an intermediate point at which the NMOS transistor 265 and the PMOS transistor 267 are connected to each other.

The buffer 26 also includes an NMOS transistor 269 and a PMOS transistor 270 as an output stage. The NMOS transistor 269 and the PMOS transistor 270 are connected in series in the stated order between the boosted potential VH and the reference potential VSS.

A gate terminal of the NMOS transistor 269 has the same potential as that of the gate terminal of the NMOS transistor 265 in the input stage, and a gate terminal of the PMOS transistor 270 has the same potential as that of the gate terminal of the PMOS transistor 267 in the input stage. In the output stage, an intermediate point at which the NMOS transistor 269 and the PMOS transistor 270 are connected to each other is an output point, and the output point is connected to a non-inverting input terminal of the operational amplifier OP4 through the sense resistor 23.

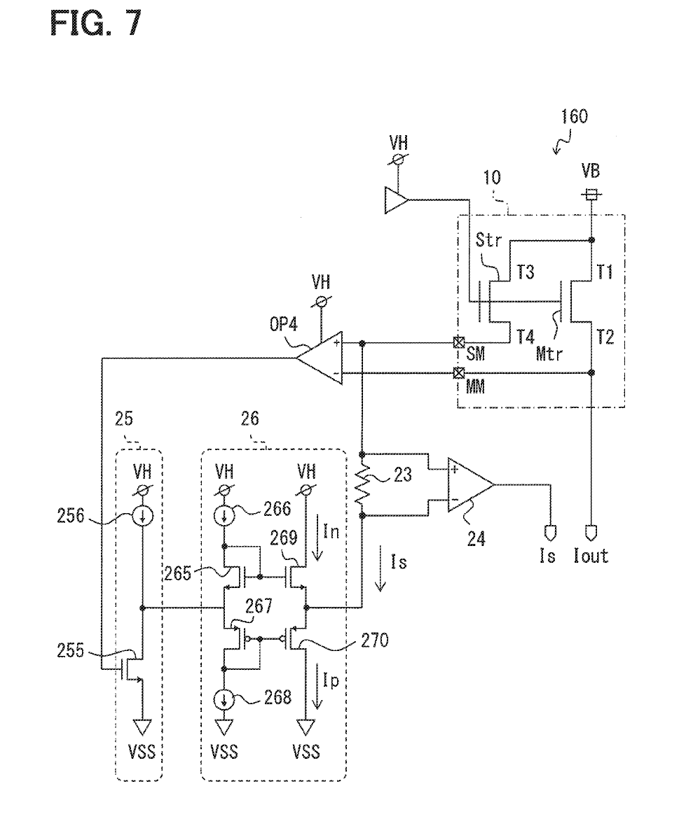

The operation of the semiconductor device 160 at the time of power running and regeneration will be briefly described below. A direction of the sense current Is at the time of power running indicated by an arrow in FIG. 7 is defined as a forward direction, a direction of the power running current Ip indicated by an arrow is defined as a positive direction, and a direction of the regenerative current In indicated by an arrow is defined as a positive direction. That is, Is=Ip−In.

<Power Running: When the Sense Current Is is Small>

At the time of power running, an output current flows from the drain terminal T1 as the first terminal of the main MOS transistor Mtr toward the source terminal T2 as the second terminal. The sense current Is also flows from the drain terminal T3 as the third terminal of the sense MOS transistor Str toward the source terminal T4 as the fourth terminal. In other words, a magnitude relationship of the potentials is MM<VB and SM<VB.

Assuming that the sense current Is is small, that is, SM>MM, the output of the operational amplifier OP4 becomes positive. As a result, a gate potential of the NMOS transistor 255 in the voltage adjustment circuit 25 rises, and an output voltage of the voltage adjustment circuit 25 drops. In other words, the input voltage of the buffer 26 drops. When the input voltage of the buffer 26 drops, the output voltage of the buffer 26 also drops. In other words, the power running current Ip increases to lower the output voltage of the buffer 26. As Ip increases, the sense current Is increases, and the potential SM of the fourth terminal decreases. That is, the feedback is performed so that SM=MM.

<Power Running: When the Sense Current Is is Large>

The magnitude relationship of the potentials is MM<VB and SM<VB. Assuming that the sense current Is is large, that is, SM<MM, the output of the operational amplifier ON becomes negative. As a result, the gate potential of the NMOS transistor 255 in the voltage adjustment circuit 25 drops, and the output voltage of the voltage adjustment circuit 25 rises.

In other words, the input voltage of the buffer 26 rises. When the input voltage of the buffer 26 rises, the output voltage of the buffer 26 also rises. In other words, the power running current Ip decreases to increase the output voltage of the buffer 26. As Ip decreases, the sense current Is decreases and the potential SM of the fourth terminal increases. That is, the feedback is performed so that SM=MM.

<Regeneration: When the Sense Current Is is Small>

At the time of regeneration, the output current flows from the source terminal T2 which is the second terminal of the main MOS transistor Mtr toward the drain terminal T1 which is the first terminal. The sense current Is also flows from the source terminal T4 which is the fourth terminal of the sense MOS transistor Str toward the drain terminal T3 which is the third terminal. That is, a magnitude relationship of the potentials is MM>VB and SM>VB.

Assuming that the sense current Is is small, that is, SM<MM, the output of the operational amplifier ON becomes negative. As a result, the gate potential of the NMOS transistor 255 in the voltage adjustment circuit 25 drops, and the output voltage of the voltage adjustment circuit 25 rises.

In other words, the input voltage of the buffer 26 rises. When the input voltage of the buffer 26 rises, the output voltage of the buffer 26 also rises. That is, the regenerative current In increases to increase the output voltage of the buffer 26. As In increases, the sense current Is increases in the negative direction, and the potential SM of the fourth terminal increases. That is, the feedback is performed so that SM=MM.

<Regeneration: When the Sense Current Is is Large>

A magnitude relationship of the potentials is MM>VB and SM>VB.

Assuming that the sense current Is is large, that is, SM>MM, the output of the operational amplifier OP4 becomes positive. As a result, a gate potential of the NMOS transistor 255 in the voltage adjustment circuit 25 rises, and an output voltage of the voltage adjustment circuit 25 drops.

In other words, the input voltage of the buffer 26 drops. When the input voltage of the buffer 26 drops, the output voltage of the buffer 26 also drops. In other words, the regenerative current In decreases to lower the output voltage of the buffer 26. As In decreases, the sense current Is decreases, and the potential SM of the fourth terminal decreases. That is, the feedback is performed so that SM=MM.

As described above, with the employment of the class AB buffer as the buffer 26, the sense current direction can be automatically switched without using a switch for switching the direction of the feedback current (sense current) of the operational amplifier OP4 at the time of power running and at the time of regeneration.

### Modification 4

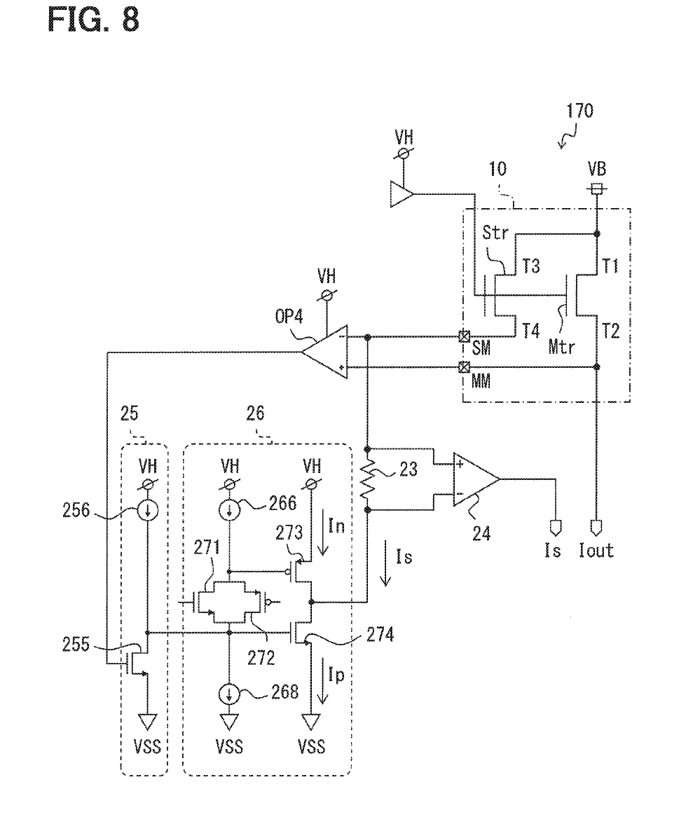

Needless to say, the class AB buffer employed in the buffer 26 is not limited to the circuit configuration shown in the above example. In the semiconductor device 160 according to the fourth embodiment, an example in which a voltage follower type class AB amplifier is employed as the buffer 26 has been described. Alternatively, as shown in FIG. 8, a class AB amplifier of a source grounded type may be employed. In this case, similarly to the third modification to the third embodiment, a connection of the non-inverting input terminal and the inverting input terminal of the operational amplifier OP4 is reversed with respect to the fourth embodiment. In other words, in a semiconductor device 170 according to the present embodiment, a source terminal T2 of a main MOS transistor Mtr is connected to a non-inverting input terminal, and a source terminal T4 of a sense MOS transistor Str is connected to an inverting input terminal.

In addition, in the semiconductor device 170, the buffer 26 is a source-grounded class AB amplifier with respect to the semiconductor device 160 in the fourth embodiment. Specifically, the buffer 26 includes an NMOS transistor 271, a PMOS transistor 272, a constant current source 266, and a constant current source 268 as an input stage. The NMOS transistor 271 and the PMOS transistor 272 are connected in parallel with each other between the constant current source 266 on the boosted potential VH side and the constant current source 268 on the reference potential VSS side. The output voltage of the voltage adjustment circuit 25 is input to the source terminal of the NMOS transistor 271.

Also, in the buffer 26, the PMOS transistor 273 and the NMOS transistor 274 are connected in series in the stated order as an output stage between the boosted potential VH and the reference potential VSS. The gate terminal of the PMOS transistor 273 has the same potential as the drain terminal of the NMOS transistor 271 in the input stage, and the gate terminal of the NMOS transistor 274 has the same potential as the source terminal of the NMOS transistor 271 in the input stage. In the output stage, an intermediate point at which the PMOS transistor 273 and the NMOS transistor 274 are connected to each other is an output point, and the output point is connected to an inverting input terminal of the operational amplifier OP4 through the sense resistor 23.

### Other Embodiments

In each of the embodiments and each of Modifications described above, an example in which the MOSFET is employed as the power switching element has been described, but the type of the power switching element is not limited. For example, an insulated gate bipolar transistor (IGBT) or another device may be employed.

Further, in each of the embodiments and each of Modifications described above, an example in which the differential and single-ended conversion amplifier is employed for the sense current detection amplifier 24 related to the detection of the sense current Is has been described, but a method of detecting the sense current flowing through the sense resistor 23 is arbitrary.

In the third embodiment and the fourth embodiment, the circuit configurations of the voltage adjustment circuit 25 and the buffer 26 are examples. The voltage adjustment circuit 25 may be a circuit capable of generating an output voltage corresponding to the output of the operational amplifier of the preceding stage, and the buffer 26 may be a circuit capable of generating an output voltage corresponding to the output of the voltage adjustment circuit 25 in a preceding stage and capable of generating a higher potential than the power supply potential VB at the time of regeneration.

Although the present disclosure is described based on the above embodiments, the present disclosure is not limited to the embodiments and the structures. Various changes and modification may be made in the present disclosure. Furthermore, various combination and formation, and other combination and formation including one, more than one or less than one element may be made in the present disclosure.

Optional aspects of the present disclosure will be set forth in the following clauses.

According to an aspect of the present disclosure, a semiconductor device includes a main switching element, a sense switching element, a sense resistor and an operational amplifier.

The main switching element controls a load current. The main switching element has a first terminal and a second terminal as output terminals between which the load current flows. The sense switching element is connected to the main switching element to form a current mirror. The sense switching element has a third terminal and a fourth terminal. The third terminal is connected to the first terminal and a sense current correlated with the load current flows between the third terminal and the fourth terminal. The sense resistor is connected to the fourth terminal and configured to detect a potential of the fourth terminal. The operational amplifier has input terminals respectively connected to the second terminal and the fourth terminal.

The operational amplifier is configured to feed an output of the operational amplifier back to one of the input terminals of the operational amplifier. The sense resistor is arranged in a feedback path of the operational amplifier. The operational amplifier is supplied with a voltage higher than a potential of the first terminal.

A direction of the sense current flowing through the sense resistor is switchable according to a magnitude relationship between the potential of the first terminal and a potential of the second terminal or a magnitude relationship between the potential of the first terminal and the potential of the fourth terminal.

According to the aspect of the present disclosure, since the sense resistor is arranged in the feedback path between the output and the input of the operational amplifier, the direction of the current flowing through the sense resistor can be switched depending on the direction of the feedback current. In other words, the direction of the sense current can be switched.

In the above configuration, for example, the direction of the sense current flowing when the potential of the fourth terminal is lower than that of a first terminal (e.g., at the time of power running) and the direction of the sense current flowing when the potential of the fourth terminal is higher than that of the first terminal (e.g., at the time of regeneration) can be set to be opposite to each other. For that reason, the current value of the sense current can be detected not only at the time of power running but also at the time of regeneration, and thus the output current of the main switching element can be detected.

Even during regeneration in which the potential of the fourth terminal is higher than that of the first terminal, since a voltage higher than that of the first terminal can be supplied to the operational amplifier, the sense current can flow toward the input terminal to which the fourth terminal is connected. In other words, the sense current in a direction opposite to that at the time of the power running state can flow at the time of regeneration.

In the above configuration, since the feedback current due to the negative feedback operation of the operational amplifier is used as the sense current, the potential difference between the output terminals of the main switching element and the sense switching element can be maintained at substantially the same value. For that reason, since the mirror ratio deviation between the main switching element and the sense switching element can be reduced, the correlation between the sense current flowing through the sense switching element and the output current flowing through the main switching element can be obtained with high accuracy. In other words, the detection of the output current flowing through the main switching element can be performed inexpensively and with high accuracy.

What is claimed is:

1. A semiconductor device comprising:
a main switching element that controls a load current, the main switching element having a first terminal and a second terminal as output terminals between which the load current flows;
a sense switching element that is connected to the main switching element to form a current mirror, the sense switching element having a third terminal and a fourth terminal, the third terminal being connected to the first terminal, and a sense current correlated with the load current flowing between the third terminal and the fourth terminal;
a sense resistor that is connected to the fourth terminal and configured to detect a potential of the fourth terminal; and
an operational amplifier that has input terminals respectively connected to the second terminal and the fourth terminal, wherein
the operational amplifier is configured to feed an output of the operational amplifier back to one of the input terminals of the operational amplifier,
the sense resistor is arranged in a feedback path of the operational amplifier,
the operational amplifier is supplied with a voltage higher than a potential of the first terminal,
a direction of the sense current flowing through the sense resistor is switchable according to a magnitude relationship between the potential of the first terminal and a potential of the second terminal or a magnitude relationship between the potential of the first terminal and the potential of the fourth terminal,
the operational amplifier includes a first operational amplifier and a second operational amplifier,
the first operational amplifier has a first non-inverting input terminal connected to the fourth terminal, and a first inverting input terminal connected to the second terminal,
a current flows from the first non-inverting input terminal toward a reference potential lower than a potential of the first terminal through the sense resistor in response to an output of the first operational amplifier,
the second operational amplifier is connected in parallel to the first operational amplifier and is supplied with a voltage higher than the potential of the first terminal,
the second operational amplifier has a second non-inverting input terminal connected to the second terminal, and a second inverting input terminal connected to the fourth terminal,
a current flows from a high voltage source higher in potential than the first terminal toward the inverting input terminal through the sense resistor in response to an output of the second operational amplifier,
the first operational amplifier is enabled and the second operation amplifier is disabled when the potential of the first terminal is higher than the potential of the second terminal, and
the first operational amplifier is disabled and the second operational amplifier is enabled when the potential of the first terminal is lower than the potential of the second terminal.

2. A semiconductor device comprising:
a main switching element that controls a load current, the main switching element having a first terminal and a second terminal as output terminals between which the load current flows;
a sense switching element that is connected to the main switching element to form a current mirror, the sense switching element having a third terminal and a fourth terminal, the third terminal being connected to the first terminal, and a sense current correlated with the load current flowing between the third terminal and the fourth terminal;
a sense resistor that is connected to the fourth terminal and configured to detect a potential of the fourth terminal;
an operational amplifier that has input terminals respectively connected to the second terminal and the fourth terminal;
a first switch circuit that is interposed between the input terminals of the operational amplifier and the second terminal and the fourth terminal; and
a second switch circuit that is interposed between an output terminal of the operational amplifier and the sense resistor, wherein
the operational amplifier is configured to feed an output of the operational amplifier back to one of the input terminals of the operational amplifier,
the sense resistor is arranged in a feedback path of the operational amplifier,
the operational amplifier is supplied with a voltage higher than a potential of the first terminal,
a direction of the sense current flowing through the sense resistor is switchable according to a magnitude relationship between the potential of the first terminal and a potential of the second terminal or a magnitude relationship between the potential of the first terminal and the potential of the fourth terminal,
the first switch circuit connects the second terminal to one of a non-inverting input terminal and an inverting input terminal of the operational amplifier, and connects the fourth terminal to the other of the non-inverting input terminal and the inverting input terminal not connected to the second terminal,
the second switch circuit allows a current to flow from the non-inverting input terminal toward a reference potential lower than the potential of the first terminal through the sense resistor in response to an output of the operational amplifier when the second terminal is connected to the non-inverting input terminal, and
the second switch circuit allows a current to flow from a high voltage source higher than the potential of the first terminal toward the inverting input terminal through the sense resistor in response to the output of the operational amplifier when the second terminal is connected to the inverting input terminal.
